(19) United States
(12) Patent Application Publication
(10) Pub. No.: US 2021/0036218 A1
(43) Pub. Date: Feb. 4, 2021

(54) SEMICONDUCTOR MEMORY DEVICE

(71) Applicant: Kioxia Corporation, Tokyo (JP)

(72) Inventor: Hiroyuki ODE, Yokkaichi Mie (JP)

(73) Assignee: Kioxia Corporation, Tokyo (JP)

(21) Appl. No.: 16/809,946

(22) Filed: Mar. 5, 2020

(30) Foreign Application Priority Data
Jul. 30, 2019 (JP) 2019-140248

(51) Int. Cl. H01L 45/00; H01L 27/24; G11C 13/00

(52) U.S. Cl. CPC H01L 45/065; H01L 45/1253; G11C 2013/009; G11C 13/0069; H01L 27/2409

(57) ABSTRACT

According to one embodiment, a semiconductor memory device includes a first electrode and a second electrode, a phase change layer disposed between the first electrode and the second electrode, and a conducting layer disposed between the first electrode and the phase change layer. The phase change layer contains a crystal having a Face-Centered Cubic lattice structure with a first lattice constant. The conducting layer contains a crystal having a Face-Centered Cubic lattice structure with a second lattice constant. The second lattice constant is larger than 80% and smaller than 120% of the first lattice constant.

### CROSS-REFERENCE TO RELATED APPLICATIONS

This application is based upon and claims the benefit of Japanese Patent Application No. 2019-140248, filed on Jul. 30, 2019, the entire contents of which are incorporated herein by reference.

### BACKGROUND

### Field

Embodiments described herein relate generally to a semiconductor memory device.

### Description of the Related Art

There has been known a semiconductor memory device that includes a first electrode and a second electrode, and a phase change layer disposed between the first electrode and the second electrode. The phase change layer contains, for example, germanium (Ge), antimony (Sb), and tellurium (Te).

### BRIEF DESCRIPTION OF THE DRAWINGS

FIG. 1 is a schematic circuit diagram illustrating a configuration of a part of a semiconductor memory device according to a first embodiment;

FIG. 2 is a schematic perspective view illustrating a configuration of a part of the semiconductor memory device;

FIGS. 3A and 3B are schematic cross-sectional views of a memory cell MC;

FIG. 4 is a schematic graph illustrating current-voltage characteristics of the memory cell MC;

FIG. 5 is a schematic cross-sectional view for describing a write operation of the memory cell MC according to the first embodiment;

FIG. 6 is a schematic cross-sectional view for describing a write operation of the memory cell MC according to a comparative example; and

FIGS. 7A and 7B are schematic cross-sectional views of the memory cell MC according to a second embodiment.

### DETAILED DESCRIPTION

A semiconductor memory device according to one embodiment includes a first electrode and a second electrode, a phase change layer disposed between the first electrode and the second electrode, and a conducting layer disposed between the first electrode and the phase change layer. The phase change layer contains a crystal having a Face-Centered Cubic lattice structure with a first lattice constant. The conducting layer contains a crystal having a Face-Centered Cubic lattice structure with a second lattice constant. The second lattice constant is larger than 80% and smaller than 120% of the first lattice constant.

A semiconductor memory device according to one embodiment includes a first electrode and a second electrode, a phase change layer disposed between the first electrode and the second electrode, and a conducting layer disposed between the first electrode and the phase change layer. The conducting layer contains any of Ni, Pd, Ir, Pt, Sr, Cu, Ce, PtO, and PdO.

A semiconductor memory device according to one embodiment includes a first electrode and a second electrode, a phase change layer disposed between the first electrode and the second electrode, and a seed crystal disposed in the phase change layer. The phase change layer contains a crystal having a Face-Centered Cubic lattice structure with a first lattice constant. The seed crystal contains a crystal having a Face-Centered Cubic lattice structure with a second lattice constant. The second lattice constant is larger than 80% and smaller than 120% of the first lattice constant.

A semiconductor memory device according to one embodiment includes a first electrode and a second electrode, a phase change layer disposed between the first electrode and the second electrode, and a seed crystal disposed in the phase change layer.

The seed crystal contains any of Ni, Pd, Ir, Pt, Sr, Cu, Ce, PtO, and PdO.

Next, semiconductor memory devices according to embodiments will be described in detail with reference to the drawings. The following embodiments are merely examples, and will not be described for the purpose of limiting the present invention.

In this specification, a predetermined direction parallel to a surface of a substrate is referred to as an X direction, a direction parallel to the surface of the substrate and perpendicular to the X direction is referred to as a Y direction, and a direction perpendicular to the surface of the substrate is referred to as a Z direction.

In this specification, a direction along a predetermined plane maybe referred to as a first direction, a direction along this predetermined plane and intersecting with the first direction may be referred to as a second direction, and a direction intersecting with this predetermined plane may be referred to as a third direction. These first direction, second direction, and third direction may correspond to any of the X direction, the Y direction, and the Z direction or need not to correspond to these directions.

Expressions such as “above” and “below” in this specification are based on the substrate. For example, a direction away from the substrate along the Z direction is referred to as above and a direction approaching the substrate along the Z direction is referred to as below. A lower surface and a lower end of a certain configuration mean a surface and an end portion on the substrate side of this configuration. A top surface and an upper end of a certain configuration mean a surface and an end portion on a side opposite to the substrate of this configuration. A surface intersecting with the X direction or the Y direction is referred to as a side surface or the like.

In this specification, when referring to that a first configuration is “electrically connected” to a second configuration, the first configuration may be directly connected to the second configuration, or the first configuration may be connected to the second configuration via wiring, a semiconductor member, a transistor, or the like. For example, when three transistors are connected in series, even when the second transistor is in OFF state, the first transistor is “electrically connected” to the third transistor.

In this specification, when referring to that the first configuration is “electrically insulated” from the second configuration, this means, for example, a state where an insulating layer or the like is disposed between the first configuration and the second configuration and a contact, a wiring, or the like to connect the first configuration to the second configuration is not disposed.

In this specification, when referring to that a circuit or the like “electrically conducts” two wirings or the like, it may mean, for example, that this circuit or the like includes a transistor or the like, this transistor or the like is disposed on a current path between the two wirings, and this transistor or the like is turned ON.

With reference to the drawings, circuit configurations of the semiconductor memory devices according to the embodiments will be described below. The following drawings are schematic, and for convenience of explanation, a part of a configuration is sometimes omitted.

### First Embodiment

[Schematic Configuration]

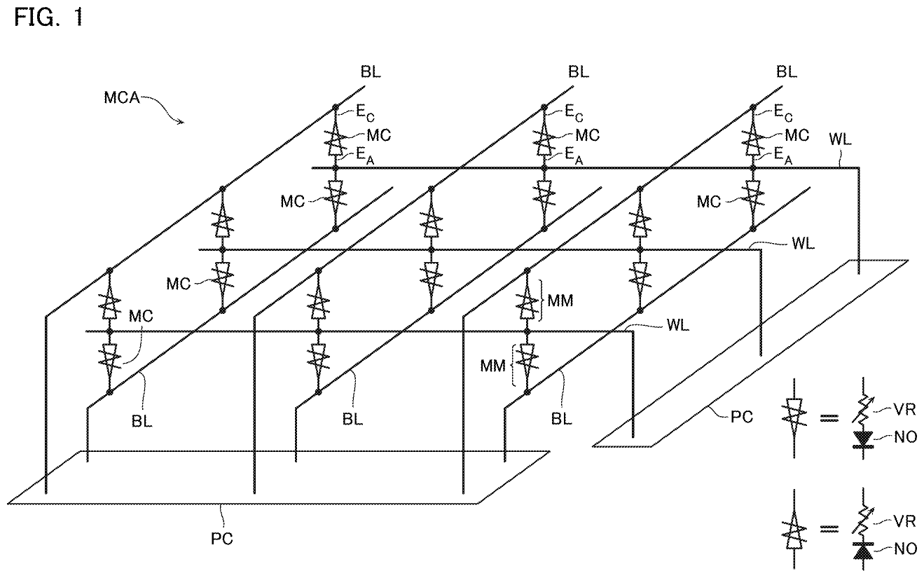

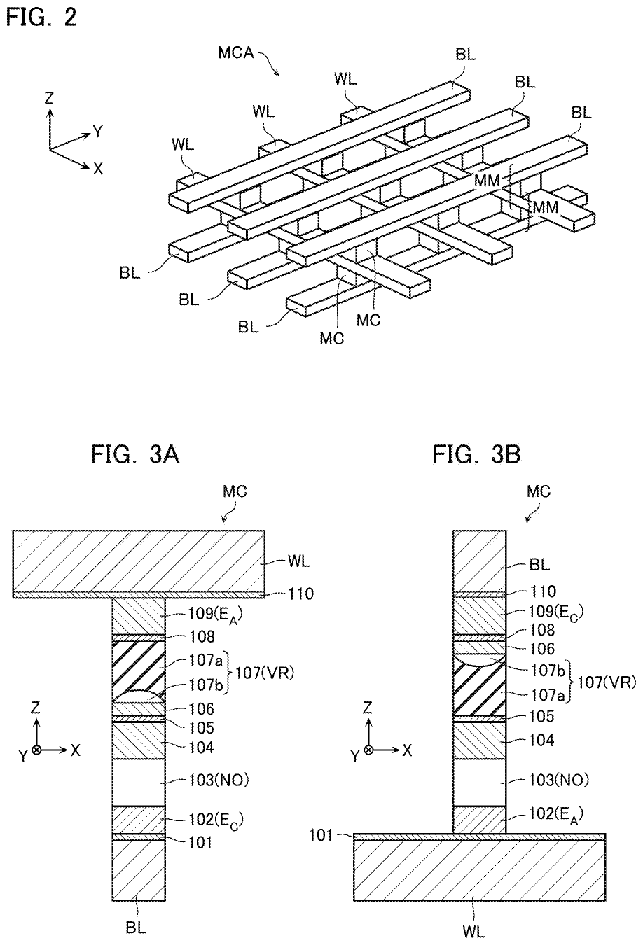

FIG. 1 is a schematic circuit diagram illustrating a configuration of a part of a semiconductor memory device according to the first embodiment. FIG. 2 is a schematic perspective view illustrating a configuration of a part of the semiconductor memory device.

The semiconductor memory device according to the embodiment includes a memory cell array MCA and a peripheral circuit PC controlling the memory cell array MCA.

For example, as illustrated in FIG. 2, the memory cell array MCA includes a plurality of memory mats MM arranged in the Z direction. The memory mat MM includes a plurality of bit lines BL arranged in the X direction and extending in the Y direction, a plurality of word lines WL arranged in the Y direction and extending in the X direction, and a plurality of memory cells MC arranged in the X direction and the Y direction corresponding to the bit lines BL and the word lines WL. As illustrated in the drawing, regarding the two memory mats MM arranged in the Z direction, the bit line BL or the word line WL may be disposed in common. In the example of FIG. 1, a cathode E_{c} of the memory cell MC is connected to the bit line BL. Additionally, an anode E_{A} of the memory cell MC is connected to the word line WL. The memory cell MC includes a variable resistance element VR and a nonlinear element NO.

The peripheral circuits PC are connected to the bit lines BL and the word lines WL. The peripheral circuit PC includes, for example, a step down circuit that steps down, for example, a power supply voltage and outputs the power supply voltage to a voltage supply line, a selection circuit that electrically conducts the bit line BL and the word line WL corresponding to a selected address and the corresponding voltage supply line, a sense amplifier circuit that outputs data of 0 or 1 according to a voltage or a current of the bit line BL, and a sequencer that controls the circuits.

[Configuration of Memory Cell MC]

FIGS. 3A and 3B are schematic cross-sectional views of the memory cell MC according to the embodiment. FIG. 3A corresponds to one that includes the bit line BL provided below the word line WL. FIG. 3B corresponds to one that includes the word line WL provided below the bit line BL.

The memory cell MC illustrated in FIG. 3A includes a conducting layer 102, a chalcogen layer 103, a conducting layer 104, a barrier conducting layer 105, a conducting layer 106, a chalcogen layer 107, a barrier conducting layer 108, and a conducting layer 109 laminated on a barrier conducting layer 101 on a top surface of the bit line BL in the order. On the conducting layer 109, a barrier conducting layer 110 on a lower surface of the word line WL is disposed.

The barrier conducting layer 101 functions as a part of the bit line BL. For example, the barrier conducting layer 101 may be any conducting layer including tungsten nitride (WN), titanium nitride (TiN), and the like, and tungsten carbonitride (WCN), tungsten carbonitride silicide (WCNSi), or the like.

The conducting layer 102 is connected to the bit line BL disposed immediately below the memory cell MC and functions as the cathode E_{c} of the memory cell MC. For example, the conducting layer 102 may be any conducting layer including carbon (C), carbon nitride (CN), tungsten (W), polycrystalline silicon into which N type impurities, such as phosphorus (P), are injected, tungsten carbide (WC), tungsten carbonitride (WCN), tungsten carbonitride silicide (WCNSi), or the like.

The chalcogen layer 103 functions as the nonlinear element NO. For example, in a case where a voltage lower than a predetermined threshold is applied to the chalcogen layer 103, the chalcogen layer 103 is in a high resistance state. When the voltage applied to the chalcogen layer 103 reaches the predetermined threshold, the chalcogen layer 103 enters a low resistance state and a current flowing through the chalcogen layer 103 increases by a plurality of digits. When the voltage applied to the chalcogen layer 103 falls below the predetermined voltage for a constant period, the chalcogen layer 103 enters the high resistance state again.

The chalcogen layer 103 contains, for example, at least one or more kinds of chalcogen. The chalcogen layer 103 may contain, for example, a chalcogenide, which is a compound containing a chalcogen. Additionally, the chalcogen layer 103 may contain at least one kind of element selected from the group consisting of B, Al, Ga, In, C, Si, Ge, Sn, As, P, and Sb.

Note that the chalcogen here means one other than oxygen (O) among elements belonging to the group 16 of the periodic table. The chalcogen contains, for example, sulfur (S), selenium (Se), and tellurium (Te).

The conducting layer 104 functions as an electrode that connects the nonlinear element NO to the variable resistance element VR. The conducting layer 104 may contain, for example, a material similar to that of the conducting layer 102.

The barrier conducting layer 105 may contain, for example, a material similar to that of the barrier conducting layer 101.

The conducting layer 106 contacts a surface on the cathode E_{c} side of the chalcogen layer 107 and functions as a crystalline base (template) configured to control a crystalline structure of the chalcogen layer 107. The conducting layer 106 contains, for example, a crystal having a Face-Centered Cubic (fcc) lattice structure (hereinafter referred to as “fcc crystal”). The conducting layer 106 has at least several or more layers made of constituent atoms described later.

The chalcogen layer 107 functions as the variable resistance element VR. As illustrated in FIGS. 3A and 3B, the chalcogen layer 107 includes, for example, a crystalline region 107a and a phase change region 107b. The crystalline region 107a contains, for example, a crystal having a Hexagonal close-packed (hcp) lattice structure (hereinafter referred to as “hcp crystal”). The phase change region 107b is disposed on the cathode E_{c} side with respect to the crystalline region 107a and contacts the conducting layer 106. For example, by heating at a melting temperature or more and rapid cooling, the phase change region 107b enters an amorphous state (reset state: high resistance state). Moreover, for example, by heating at a temperature lower than a melting temperature and higher than a crystallization temperature, the phase change region 107b enters a crystalline state (set state: low resistance state).

The chalcogen layer 107 contains, for example, at least one or more kinds of chalcogen. The chalcogen layer 107 may contain, for example, a chalcogenide, which is a compound containing a chalcogen. The chalcogen layer 107 may be, for example, GeSbTe, GeCuTe, GeTe, SbTe, and SiTe. The chalcogen layer 107 may contain at least one kind of element selected from germanium (Ge), antimony (Sb), and tellurium (Te).

The barrier conducting layer 108 may contain, for example, a material similar to that of the barrier conducting layer 101.

The conducting layer 109 is connected to the word line WL disposed immediately above the memory cell MC and functions as the anode E_{A} of the memory cell MC. The conducting layer 109 may contain, for example, a material similar to that of the conducting layer 102.

The barrier conducting layer 110 functions as a part of the word line WL. The barrier conducting layer 110 may contain, for example, a material similar to that of the barrier conducting layer 101.

The memory cell MC illustrated in FIG. 3B is basically configured similarly to the memory cell MC illustrated in FIG. 3A. However, the memory cell MC illustrated in FIG. 3B includes the conducting layer 106 between the chalcogen layer 107 and the barrier conducting layer 108, not between the barrier conducting layer 105 and the chalcogen layer 107. Additionally, in the memory cell MC illustrated in FIG. 3B, not the barrier conducting layer 101 but the barrier conducting layer 110 functions as a part of the bit line BL, and not the barrier conducting layer 110 but the barrier conducting layer 101 functions as a part of the word line WL. Further, not the conducting layer 102 but the conducting layer 109 functions as the cathode E_{c}, and not the conducting layer 109 but the conducting layer 102 functions as the anode E_{A}.

[Electric Characteristics of Memory Cell MC]

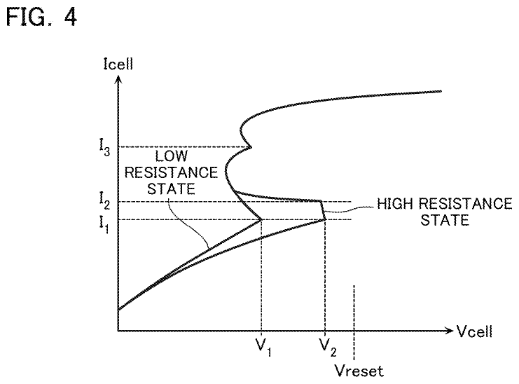

FIG. 4 is a schematic graph illustrating current-voltage characteristics of the memory cell MC according to the embodiment. The horizontal axis indicates a voltage of the anode E_{A} (hereinafter referred to as “cell voltage Vcell”) when a voltage of the cathode E_{c} of the memory cell MC is set as a reference. The vertical axis indicates a current flowing through the memory cell MC (hereinafter referred to as “cell current Icell”) by logarithmic axis.

In a range where a value of the cell current Icell is smaller than a value of a predetermined current value I₁, the cell voltage Vcell monotonously increases according to an increase in the cell current Icell. At a point when the cell current Icell reaches the current value I₁, the cell voltage Vcell of the memory cell MC in the low resistance state reaches a voltage V₁. The cell voltage Vcell of the memory cell MC in the high resistance state reaches a voltage V₂. The voltage V₂ is higher than the voltage V₁.

In a range where the value of the cell current Icell is larger than a value of a current value I₁ and smaller than a current value I₂, the cell voltage Vcell monotonously decreases according to an increase in the cell current Icell. In the range, the cell voltage Vcell of the memory cell in the high resistance state is higher than the cell voltage Vcell of the memory cell MC in the low resistance state.

In a range where the cell current Icell is larger than the current value 1₂ and smaller than a current value 1₃, the cell voltage Vcell temporarily decreases according to the increase in the cell current Icell and increases thereafter.

In the range, according to the increase in the cell current Icell, the cell voltage Vcell of the memory cell MC in the high resistance state rapidly decreases and becomes approximately same as the cell voltage Vcell of the memory cell MC in the low resistance state.

In a range where the cell current Icell is larger than the current value 1₃, the cell voltage Vcell temporarily decreases according to the increase in the cell current Icell and increases thereafter.

In a case where the cell current Icell is rapidly decreased down to a magnitude smaller than the current value I₁ from this state, the chalcogen layer 107 enters the high resistance state. Alternatively, in a case where the cell current Icell is decreased down to a predetermined magnitude and the cell current Icell is decreased after the state is maintained for a certain period of time, the chalcogen layer 107 enters the low resistance state.

[Operation]

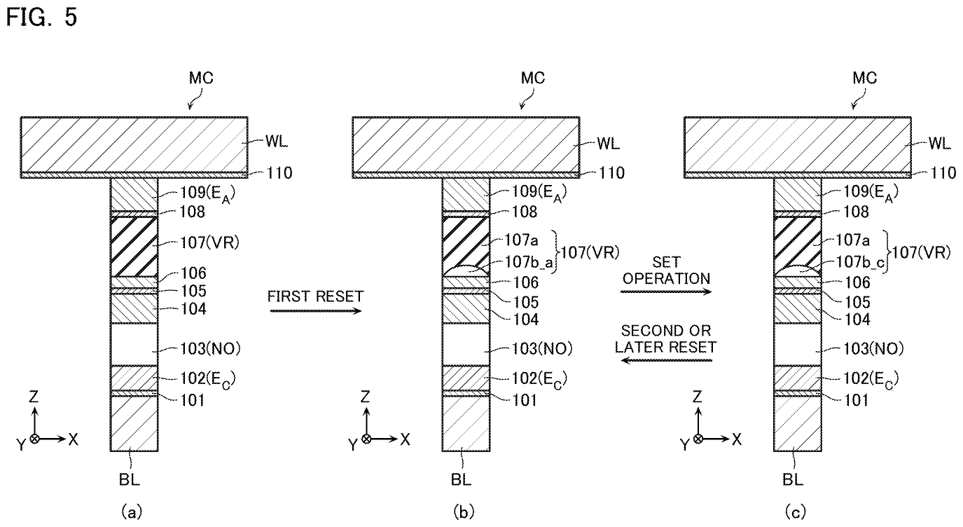

FIG. 5 is a schematic cross-sectional view for describing a write operation of the memory cell MC according to the embodiment. The drawings illustrate a set operation and a reset operation as examples of the write operation. The set operation is an operation that causes the memory cell MC to transition from the high resistance state to the low resistance state. The reset operation is an operation that causes the memory cell MC to transition from the low resistance state to the high resistance state.

FIG. 5 includes: a left part (a) illustrating a state of the memory cell MC before performing a first reset operation as the initial reset operation; a middle part (b) illustrating a state of the memory cell MC after performing the reset operation; and a right part (c) illustrating a state of the memory cell MC after performing the set operation.

Note that, in the following description, an example where the main component of the chalcogen layer 107 is Ge₂Sb₂Te₅ will be described.

The chalcogen layer 107 in the left part (a) of FIG. 5 is in the state before the first reset operation is performed and after manufacturing. The chalcogen layer 107 in the left part (a) of FIG. 5 mainly contains an hcp crystal.

When the reset operation is performed on the memory cell MC illustrated in the left part (a) of FIG. 5, as illustrated in the middle part of FIG. 5, a phase change region 107b a in the amorphous state is formed in the chalcogen layer 107. In the reset operation, for example, the cell voltage Vcell is adjusted to a reset voltage Vreset higher than the voltage V₂ (FIG. 4). Thus, a current flows through the memory cell MC and Joule heat is supplied to the phase change region 107b. The Joule heat at this time has a magnitude to a degree where apart of the chalcogen layer 107 melts. Next, the cell voltage Vcell is decreased down to 0 V. Thus, the Joule heat is no longer supplied to the chalcogen layer 107, and a melted part of the chalcogen layer 107 is rapidly cooled. During this period, a period required for crystallization is not given to the chalcogen layer 107. Therefore, the melted part is solidified as the amorphous state (reset state: high resistance state), thus forming the phase change region 107b a in the amorphous state.

Note that, in the following description, a current flowing through the memory cell MC during the reset operation is referred to as Ireset.

When the set operation is performed on the memory cell MC illustrated in the middle part (b) of FIG. 5, as illustrated in the right part (c) of FIG. 5, the phase change region 107b_a in the amorphous state becomes a phase change region 107b_c in the crystalline state. In the set operation, for example, the cell voltage Vcell is adjusted to be a set voltage Vset smaller than the reset voltage Vreset and the state is held for a certain period of time. This flows the current to the memory cell MC and the Joule heat is supplied to the phase change region 107b_a. The Joule heat at this time has a magnitude of a degree where the phase change region 107b_a is crystallized but melting does not occur. Additionally, the set voltage Vset is held for a required period for the phase change region 107b to be crystallized. Afterwards, the cell voltage Vcell is set to 0 V. Thus, the phase change region 107b_a in the amorphous state becomes the phase change region 107b_c in the crystalline state (set state: low resistance state).

Note that, in the set operation, the crystal of Ge₂Sb₂Te₅ in the phase change region 107b grows with a crystal face of the fcc crystal contained in the conducting layer 106 as its base. Accordingly, the fcc crystal is mainly generated in the phase change region 107b.

When the reset operation is performed on the memory cell MC illustrated in the right part (c) of FIG. 5, as illustrated in the middle part (b) of FIG. 5, the phase change region 107b_c in the crystalline state becomes the phase change region 107b_a in the amorphous state.

After that, similarly, when the set operation is performed on the memory cell MC illustrated in the middle part (b) of FIG. 5, the phase change region 107b_a in the amorphous state becomes the phase change region 107b_c in the crystalline state. Additionally, when the reset operation is performed on the memory cell MC illustrated in the right part (c) of FIG. 5, the phase change region 107b_c in the crystalline state becomes the phase change region 107b a in the amorphous state.

### Comparative Example

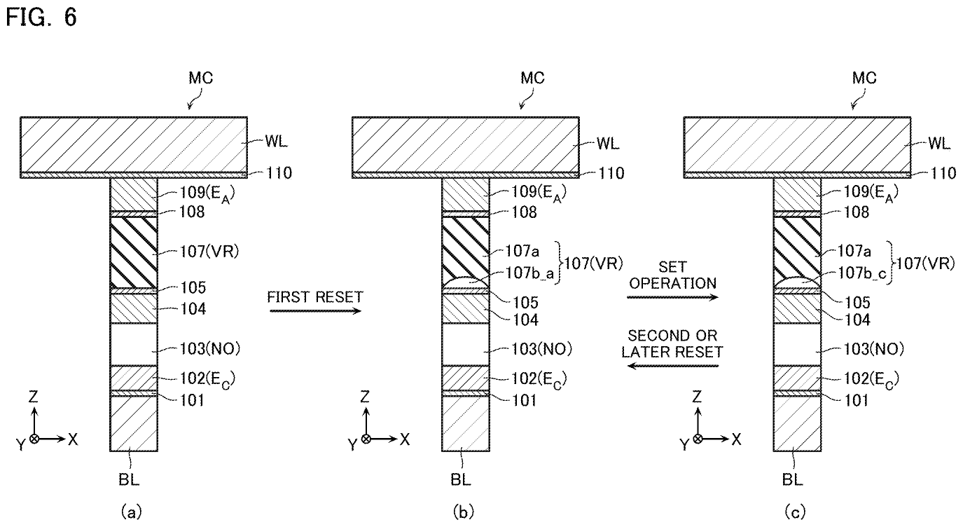

FIG. 6 is a schematic cross-sectional view for describing the write operation of the memory cell MC according to the comparative example. The memory cell MC according to the comparative example is basically configured similarly to the memory cell MC according to the first embodiment. However, the memory cell MC according to the comparative example does not include the conducting layer 106.

FIG. 6 includes: a left part (a) illustrating a state of the memory cell MC before performing the first reset operation as the initial reset operation; a middle part (b) illustrating a state of the memory cell MC after performing the reset operation; and a right part (c) illustrating a state of the memory cell MC after performing the set operation.

As illustrated in FIG. 6, the set operation and the reset operation of the memory cell MC according to the comparative example are performed similarly to the set operation and the reset operation of the memory cell MC according to the first embodiment. However, the memory cell MC according to the comparative example does not include the conducting layer 106. Therefore, in the set operation, compared with the first embodiment, the crystal having the hcp structure is likely to be generated in the phase change region 107b_c and the crystal having the fcc structure is less likely to be generated.

[Effects]

From aspects of a stable switching operation and lower power consumption, the reset current Ireset is preferably low. Here, the value of the reset current Ireset required for the reset operation differs depending on a composition, a crystalline structure, and the like of the chalcogen layer 107 forming the phase change region 107b. This is because a heat amount required for the phase change region 107b to melt differs depending on the composition, the crystalline structure, and the like of the chalcogen layer 107.

For example, Ge₂Sb₂Te₅ has the hcp lattice structure as the crystalline structure in a stable state, and has the fcc lattice structure as the crystalline structure in a metastable state. Here, it has been known that Ge₂Sb₂Te₅ with the fcc lattice structure is melted with heat energy smaller than that of Ge₂Sb₂Te₅ with the hcp lattice structure. Therefore, when a large amount of crystal having the fcc structure is contained in the phase change region 107b, the heat amount required for melting can be small, and therefore the reset current Ireset can be decreased.

However, it is sometimes difficult to generate the crystal having the fcc lattice structure in the phase change region 107b. Especially, in a case where the set operation is performed while, for example, the entire semiconductor memory device has a high temperature due to its long-term use, a proportion of the crystal having the hcp lattice structure increases in some cases.

Therefore, in the embodiment, for example, as described with reference to FIGS. 3A and 3B and the like, the conducting layer 106 containing the fcc crystal is disposed on the cathode E_{c} side of the chalcogen layer 107. In such a structure, as described above, in the set operation, the crystal, such as Ge₂Sb₂Te₅, in the phase change region 107b grows with the crystal face of the fcc crystal contained in the conducting layer 106 as its base. Therefore, the crystal having the fcc structure can be stably generated in the phase change region 107b. Thus, the stable switching operation and lower power consumption can be achieved with the low reset current Ireset.

[Configuration of Conducting Layer 106]

As described with reference to FIGS. 3A and 3B and the like, the conducting layer 106 contains the fcc crystal. Examples of a material constituting the fcc crystal include Sr (0.608 nm), Ce (0.516 nm), Pt0 (0.515 nm), Pd0 (0.565 nm), Ni (0.353 nm), Pd (0.389 nm), Ir (0.384 nm), Pt (0.393 nm), and Cu (0.362 nm) (the value in the parentheses indicates a lattice constant of the fcc crystal constituted by each material). The conducting layer 106 may contain, for example, at least one of the materials.

Additionally, the lattice constant of the fcc crystal contained in the conducting layer 106 is preferably close to the lattice constant of the fcc crystal contained in the phase change region 107b in the chalcogen layer 107. This is because, when these crystals have the lattice constants close to one another, the crystalline structure of the crystal contained in the phase change region 107b is more preferably controllable. Especially, the lattice constant of the crystal contained in the conducting layer 106 is preferably larger than 80% and smaller than 120% of the lattice constant of the crystal contained in the chalcogen layer 107.

For example, in a case where the chalcogen layer 107 contains Ge₂Sb₂Te₅, since the lattice constant of the fcc crystal of Ge₂Sb₂Te₅ is 0.598 nm, the fcc crystal contained in the conducting layer 106 preferably has the lattice constant same extent to this lattice constant. The material of the conducting layer 106 is preferably, for example, Sr (0.608 nm), Ce (0.516 nm), Pt0 (0.515 nm), and Pd0 (0.565 nm) (the value in the parentheses indicates the lattice constant of each material).

For example, in a case where the chalcogen layer 107 contains GeCu₂Te₃, since the lattice constant of the fcc crystal of GeCu₂Te₃ is 0.599 nm, the fcc crystal contained in the conducting layer 106 preferably has the lattice constant same extent to this lattice constant. The material of the conducting layer 106 is preferably, for example, Sr (0.608 nm), Ce (0.516 nm), Pt0 (0.515 nm), and Pd0 (0.565 nm) (the values in the parentheses indicate the lattice constants).

Note that, in the case where the chalcogen layer 107 contains another material, the lattice constant of the fcc crystal contained in the conducting layer 106 is preferably larger than 80% and smaller than 120% of the lattice constant of the fcc crystal contained in the chalcogen layer 107 similarly.

Note that composition ratios of the respective materials in the chalcogen layer 107 and the conducting layer 106 are observable by a method, such as Energy Dispersive X-ray Spectrometry (EDS). Moreover, it is possible to set an approximate line by least-square method or the like or perform moving average processing or the like on the composition ratio obtained by the method, such as EDS, and determine the composition ratio based on the result.

Additionally, the crystalline structures, the lattice constants, and the like of the crystals contained in the chalcogen layer 107 and the conducting layer 106 can be analyzed by a method, such as Nano Beam Diffraction (NBD).

### Second Embodiment

[Configuration of Memory Cell MC]

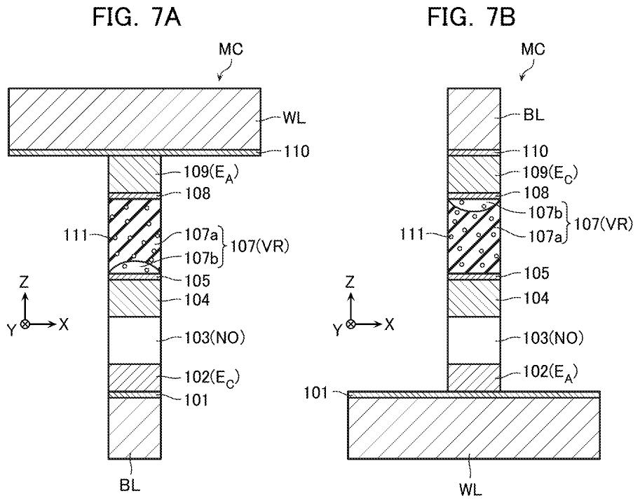

FIGS. 7A and 7B are schematic cross-sectional views of the memory cell MC according to the second embodiment. FIG. 7A corresponds to one that includes the bit line BL provided below the word line WL. FIG. 7B corresponds to one that includes the word line WL provided below the bit line BL.

As illustrated in FIGS. 7A and 7B, similarly to the first embodiment, the memory cell MC according to the embodiment includes the conducting layer 102, the chalcogen layer 103, the conducting layer 104, the barrier conducting layer 105, the chalcogen layer 107, the barrier conducting layer 108, and the conducting layer 109 laminated in the order in the Z direction. Meanwhile, different from the first embodiment, the memory cell MC according to the embodiment does not include the conducting layer 106. In the embodiment, a plurality of conductive seed crystals 111 are disposed in the chalcogen layer 107.

At least some of the plurality of conductive seed crystals 111 contact the phase change region 107b in the chalcogen layer 107. The conductive seed crystal 111 functions as a seed crystal (template) configured to control the crystalline structure of the chalcogen layer 107. Note that the conductive seed crystal 111 contains, for example, the material similar to that of the conducting layer 106 according to the first embodiment. The conductive seed crystal 111 contains the fcc crystal, and the lattice constant of the fcc crystal is larger than 80% and smaller than 120% of the lattice constant of the fcc crystal contained in the chalcogen layer 107.

Note that content of the conductive seed crystal 111 in the chalcogen layer 107 is preferably 10% or less in terms of volume weight ratio. This is because when the content is larger than that, the function of the chalcogen layer 107 as the variable resistance element VR is possibly deteriorated.

[Effects]

In the set operation according to the embodiment, the crystal, such as Ge₂Sb₂Te₅, in the phase change region 107b grows with the crystal face of the fcc crystal contained in the conductive seed crystal 111 as its base. Thus, the stable switching operation and lower power consumption can be achieved with the low reset current Ireset.

### Other Embodiments

The semiconductor memory devices according to the first embodiment and the second embodiment have been described. However, the above-described semiconductor memory devices are merely examples, and a specific configuration and the like are appropriately adjustable.

For example, in the example of FIG. 2, the two memory mats MM are arranged in the Z direction, the lower memory mat MM includes the bit line BL positioned below the memory cell MC and the word line WL positioned above the memory cell MC, and the upper memory mat MM includes the word line WL positioned below the memory cell MC and the bit line BL positioned above the memory cell MC. The word line WL is disposed on the lower memory mat MM and the upper memory mat MM in common. However, such a configuration is merely an example, and, for example, the bit line BL illustrated in FIG. 2 may be replaced by the word line WL and the word line WL illustrated in FIG. 2 may be replaced by the bit line BL.

[Others]

While certain embodiments have been described, these embodiments have been presented by way of example only, and are not intended to limit the scope of the inventions. Indeed, the novel methods and systems described herein may be embodied in a variety of other forms: furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a first electrode and a second electrode;
a phase change layer disposed between the first electrode and the second electrode; and
a conducting layer disposed between the first electrode and the phase change layer, wherein
the phase change layer contains a crystal having a Face-Centered Cubic lattice structure with a first lattice constant,
the conducting layer contains a crystal having a Face-Centered Cubic lattice structure with a second lattice constant, and
the second lattice constant is larger than 80% and smaller than 120% of the first lattice constant.

2. The semiconductor memory device according to claim 1, wherein
the conducting layer is made of the crystal having the Face-Centered Cubic lattice structure with the second lattice constant.

3. The semiconductor memory device according to claim 1, wherein
the phase change layer is connected to the conducting layer.

4. The semiconductor memory device according to claim 1, wherein
when a reset operation is performed on the phase change layer:
the phase change layer includes a first region in an amorphous state; and
the first region is connected to the conducting layer.

5. The semiconductor memory device according to claim 1, wherein
a voltage of the first electrode becomes smaller than a voltage of the second electrode in a write operation.

6. A semiconductor memory device comprising:
a first electrode and a second electrode;
a phase change layer disposed between the first electrode and the second electrode; and
a conducting layer disposed between the first electrode and the phase change layer, wherein the conducting layer contains any of Ni, Pd, Ir, Pt, Sr, Cu, Ce, PtO, and PdO.

7. The semiconductor memory device according to claim 6, wherein
the phase change layer is connected to the conducting layer.

8. The semiconductor memory device according to claim 6, wherein
when a reset operation is performed on the phase change layer:
the phase change layer includes a first region in an amorphous state; and
the first region is connected to the conducting layer.

9. The semiconductor memory device according to claim 6, wherein
a voltage of the first electrode becomes smaller than a voltage of the second electrode in a write operation.

10. A semiconductor memory device comprising:
a first electrode and a second electrode;
a phase change layer disposed between the first electrode and the second electrode; and
a seed crystal disposed in the phase change layer, wherein
the phase change layer contains a crystal having a Face-Centered Cubic lattice structure with a first lattice constant,
the seed crystal contains a crystal having a Face-Centered Cubic lattice structure with a second lattice constant, and
the second lattice constant is larger than 80% and smaller than 120% of the first lattice constant.

11. The semiconductor memory device according to claim 10, wherein
the seed crystal is made of the crystal having the Face-Centered Cubic lattice structure with the second lattice constant.

12. The semiconductor memory device according to claim 10, wherein
the phase change layer is connected to the seed crystal.

13. The semiconductor memory device according to claim 10, wherein
when a reset operation is performed on the phase change layer:
the phase change layer includes a first region in an amorphous state; and
the first region is connected to the seed crystal.

14. The semiconductor memory device according to claim 10, wherein
a voltage of the first electrode becomes smaller than a voltage of the second electrode in a write operation.

15. A semiconductor memory device comprising:
a first electrode and a second electrode;
a phase change layer disposed between the first electrode and the second electrode; and
a seed crystal disposed in the phase change layer, wherein the seed crystal contains any of Ni, Pd, Ir, Pt, Sr, Cu, Ce, PtO, and PdO.

16. The semiconductor memory device according to claim 15, wherein
the phase change layer is connected to the seed crystal.

17. The semiconductor memory device according to claim 15, wherein
when a reset operation is performed on the phase change layer:
the phase change layer includes a first region in an amorphous state; and
the first region is connected to the seed crystal.

18. The semiconductor memory device according to claim 15, wherein
a voltage of the first electrode becomes smaller than a voltage of the second electrode in a write operation.
